(19) United States
(12) Patent Application Publication
(10) Pub. No.: US 2024/0096891 A1
(43) Pub. Date: Mar. 21, 2024

(54) SELF-ALIGNED BACKSIDE CONTACT

(71) Applicant: International Business Machines Corporation, Armonk, NY (US)

(72) Inventors: Ruilong Xie, Niskayuna, NY (US); Julien Frougier, ALBANY, NY (US); Min Gyu Sung, Latham, NY (US); Chanro Park, Clifton Park, NY (US); Juntao Li, Cohoes, NY (US)

(21) Appl. No.: 17/946,821

(22) Filed: Sep. 16, 2022

(51) Int. Cl. H01L 27/092; H01L 21/8238; H01L 23/528; H01L 29/06; H01L 29/08; H01L 29/66; H01L 29/775; H01L 29/786

(52) U.S. Cl. CPC H01L 27/0924; H01L 21/823814; H01L 21/823871; H01L 23/5283; H01L 29/0673; H01L 29/0847; H01L 29/66439; H01L 29/66545; H01L 29/775; H01L 29/78696

(57) ABSTRACT

A CMOS apparatus includes a semiconductor substrate that has a frontside and a backside opposite the frontside; a source/drain structure, which is disposed at the frontside of the substrate and has a backside that is adjacent to the substrate and a frontside that is opposite the backside of the source/drain structure; a backside interconnect layer, which is disposed at the backside of the substrate; a backside contact, which penetrates the substrate and electrically connects the source/drain structure to the backside interconnect layer; and a sigma-profiled dielectric structure that insulates first and second sides of the backside contact from the substrate.

### BACKGROUND

The present invention relates to the electrical, electronic, and computer arts, and more specifically, to signal routing in semiconductor devices.

Typically, a complementary metal-oxide-semiconductor (CMOS) apparatus includes a pair of field effect transistors (FETs), one of them being n-doped (nFET) and the other p-doped (pFET). A CMOS apparatus can include, for example, a logic gate such as an inverter. In the non-limiting example of a CMOS inverter, a voltage signal is input to the coupled gates and a voltage signal is output at the coupled drains, with power connections to the sources (e.g., supply voltage on the source of the PFET and the source of the NFET grounded). Generally, electrical power/signals are supplied to sources and gates of the FETs via source and gate contacts, and the output voltage signals appear on the drains of the FETs which are connected to drain contacts. Typically, the source, gate, and drain contacts all are arranged in a “frontside” or “back-end-of-line (BEOL)” portion of the CMOS apparatus, which is nominally “above” the FETs in that the contacts are on an opposite side of the FETs from the substrate on which the FETs are formed. In some CMOS apparatus, however, the source contacts are arranged at a “backside” of the apparatus, rather than being “frontside” in the BEOL. Generally, such backside contacts present difficulties in fabrication, at least because it can be difficult to align backside contacts to the source/drain structures. Additionally, forming a backside contact typically involves replacing an interlayer dielectric for the entirety of the semiconductor substrate. Such a replacement process typically risks exposing and damaging backside surfaces of the source/drain and gate structures in the transistors of the apparatus.

### SUMMARY

Principles of the invention provide techniques for self-aligned backside contacts.

According to one aspect, an exemplary CMOS apparatus includes a semiconductor substrate that has a frontside and a backside opposite the frontside; and a first source/drain structure, which is disposed at the frontside of the substrate, and has a backside that contacts the frontside of the substrate and a frontside that is opposite the backside of the first source/drain structure. The CMOS apparatus also includes a frontside interconnect layer, which is disposed at the frontside of the first source/drain structure; a frontside contact that electrically connects the first source/drain structure to the frontside interconnect layer. The CMOS apparatus also includes a second source/drain structure, which is disposed at the frontside of the substrate and has a backside that is adjacent to the substrate and a frontside that is opposite the backside of the second source/drain structure; a backside interconnect layer, which is disposed at the backside of the substrate; a backside contact, which penetrates the substrate and electrically connects the second source/drain structure to the backside interconnect layer; and a sigma-profiled dielectric structure that insulates first and second sides of the backside contact from the substrate.

According to another aspect, an exemplary CMOS apparatus includes a semiconductor substrate that has a frontside and a backside opposite the frontside; a source/drain structure, which is disposed at the frontside of the substrate and has a backside that is adjacent to the substrate and a frontside that is opposite the backside of the source/drain structure; a backside interconnect layer, which is disposed at the backside of the substrate; a backside contact, which penetrates the substrate and electrically connects the source/drain structure to the backside interconnect layer; and a sigma-profiled dielectric structure that insulates first and second sides of the backside contact from the substrate.

According to another aspect, an exemplary method for making a CMOS apparatus includes several steps. First, form a precursor structure, which comprises a substrate and a sigma-profiled dielectric plug embedded in the substrate. Next, open a trench from a frontside of the substrate through the dielectric structure, thereby exposing the substrate at a backside end of the trench. Then, epitaxially grow a sacrificial placeholder in the trench from the substrate through the dielectric structure. Furthermore, epitaxially grow a first source/drain structure from the sacrificial placeholder at the frontside of the substrate.

In view of the foregoing, techniques of the present invention can provide substantial beneficial technical effects. For example, one or more embodiments provide one or more of:

A backside source/drain contact that is formed without removing all of the semiconductor substrate.

A backside source/drain contact that is insulated from remnants of the semiconductor substrate, without bottom dielectric isolation.

Some embodiments may not have these potential advantages and these potential advantages are not necessarily required of all embodiments. These and other features and advantages of the present invention will become apparent from the following detailed description of illustrative embodiments thereof, which is to be read in connection with the accompanying drawings.

### BRIEF DESCRIPTION OF THE DRAWINGS

FIG. 1 through FIG. 3 depict, in schematics, a CMOS apparatus that includes a self-aligned backside contact, according to exemplary embodiments, with FIGS. 1 and 2 comprising sectional views along lines 1 and 2 respectively in the plan view of FIG. 3.

FIG. 4 depicts, in a flowchart, a method for making the CMOS apparatus that is shown in FIG. 1 through FIG. 3.

FIG. 5 through FIG. 52 depict, in schematics, intermediate structures that are formed by steps of the method that is shown in FIG. 4; for each intermediate structure, the first two figures are sectional views taken along the corresponding numbered lines of the plan view.

### DETAILED DESCRIPTION

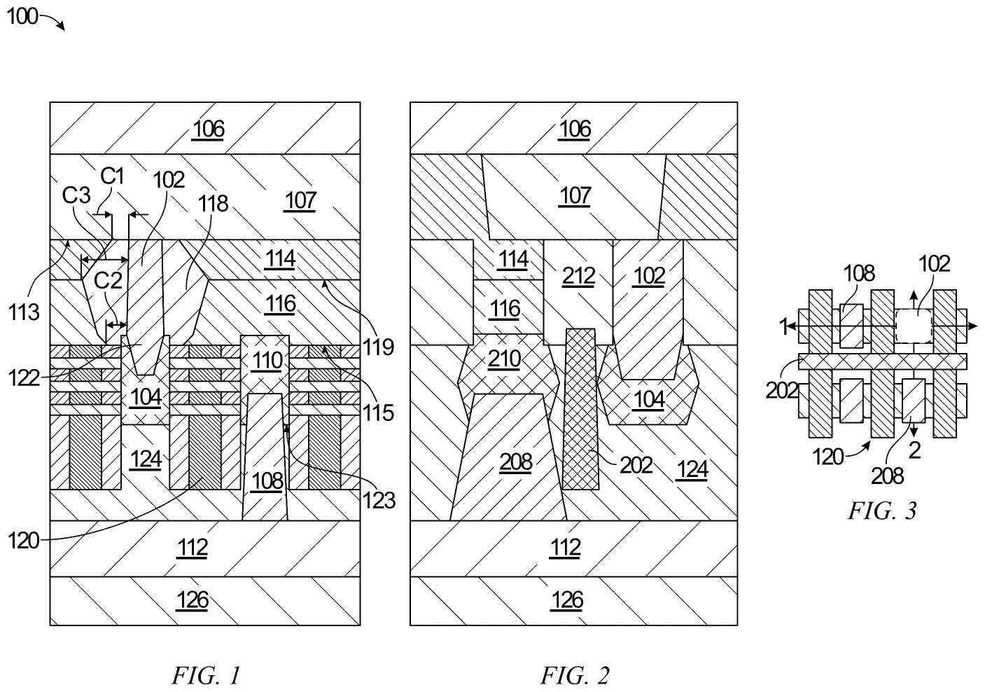

FIG. 1 through FIG. 3 depict, in schematics, a CMOS apparatus 100 that includes a self-aligned backside contact (SABC) 102, according to exemplary embodiments. FIG. 1 and FIG. 2 are taken at view lines 1 and 2, respectively, of FIG. 3.

As shown in FIG. 1, the SABC 102 electrically connects a first source/drain structure 104 to a backside interconnect layer 106 that includes a backside power rail (BSPR) 107. The CMOS apparatus 100 also includes a conventional frontside contact 108, which electrically connects a second source/drain structure 110 with a frontside interconnect layer 112. A backside interlayer dielectric (BILD) 114 insulates the BSPR 107 from a semiconductor substrate 116. A separate sigma-profiled (discussed immediately below) dielectric structure 118 insulates the SABC 102 from the substrate 116.

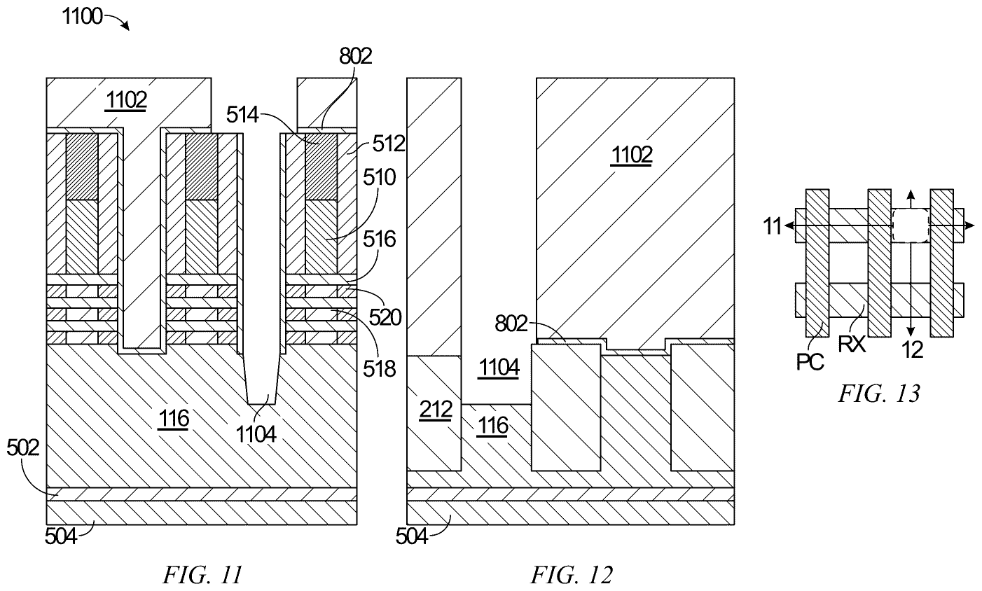

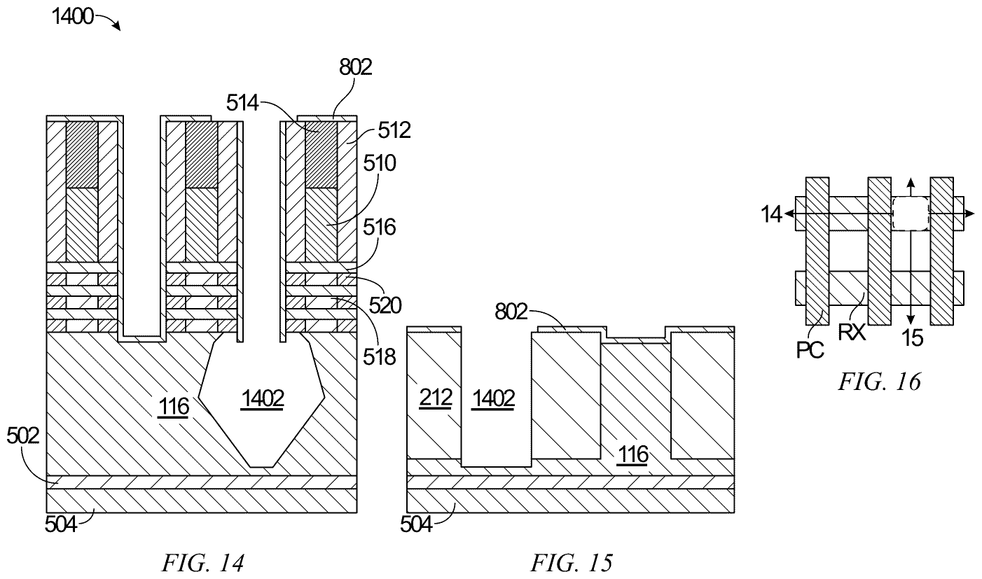

In this disclosure, “sigma-profiled” refers to the shape of a cavity 1402 (shown in FIG. 14 and FIG. 15) that is formed by isotropic etching from an indentation 1104 (shown in FIG. 11 and FIG. 12) into the substrate 116. The sigma-profiled shape is defined by three critical dimensions C1, C2, C3. In one or more embodiments, C1 is the smallest width of the shape, C2 is an intermediate width, and C3 is the largest width of the shape. In other embodiments, C1 may be larger than C2. C3 is the largest width in all embodiments. C1 is aligned with an interface 113 between the backside power rail 107 and the BILD 114. C2 is aligned with a frontside 115 of the substrate 116. In one or more embodiments, C3 is aligned close to an interface 119 between the BILD 114 and the substrate 116, i.e., the backside of the substrate 116. In other embodiments, C3 is offset from the interface 119.

A gate stack 120 physically separates and electrically connects the first and second source/drain structures 104, 110 (nanosheet channel structures electrically connect the first and second source-drain structures when the surrounding gate structure is energized). In one or more embodiments, the gate stack 120 is a high-k/metal gate stack. The ordinary skilled worker is familiar with gate stacks.

In one or more embodiments, the SABC 102 includes a nose 122 that protrudes into the backside of the first source/drain structure 104. In one or more embodiments, the frontside contact 108 similarly protrudes into a frontside 123 of the second source/drain structure 110.

Interlayer dielectric 124 insulates the first and second source/drain structures from the frontside interconnect layer 112.

The entire apparatus 100, at this stage in its fabrication, is mounted onto a carrier wafer 126. Later in fabrication, the carrier wafer 126 can optionally be removed, e.g., by chemical-mechanical polishing, by another planarization method, or by debonding.

Referring to FIG. 2, in a section perpendicular to that shown in FIG. 1, the CMOS apparatus 100 also includes a gate cut 202 (which is filled with a dielectric), a third contact 208, a third source/drain structure 210, and shallow trench isolation 212. The third contact 208 electrically connects the third source/drain structure 210 to the frontside interconnect layer 112. The shallow trench isolation 212 insulates the source/drain structures from each other.

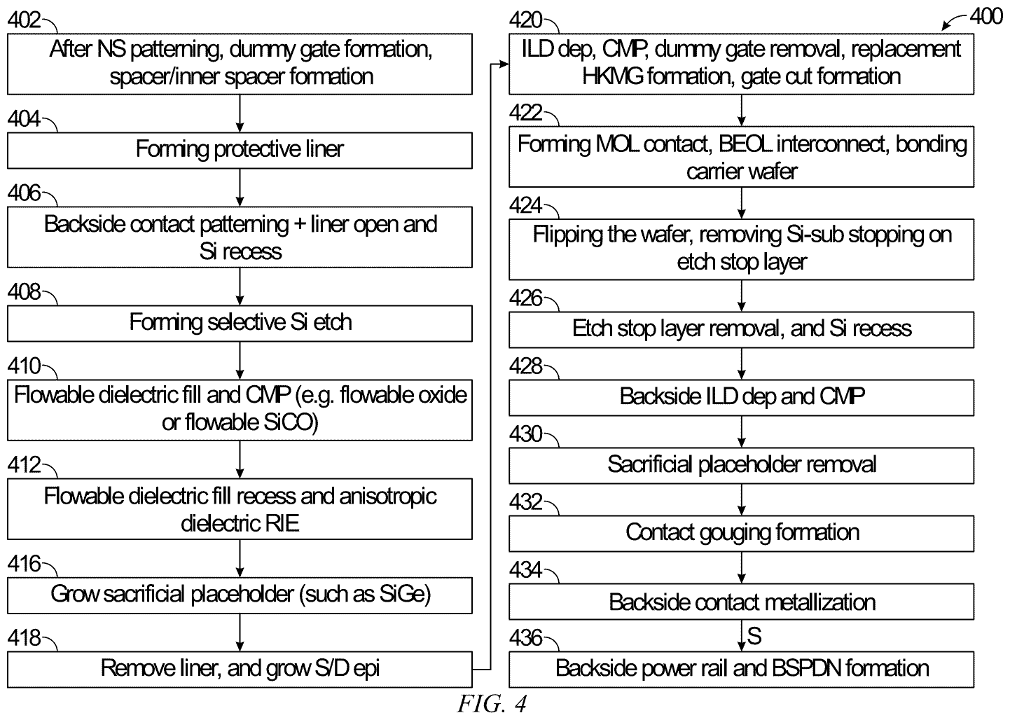

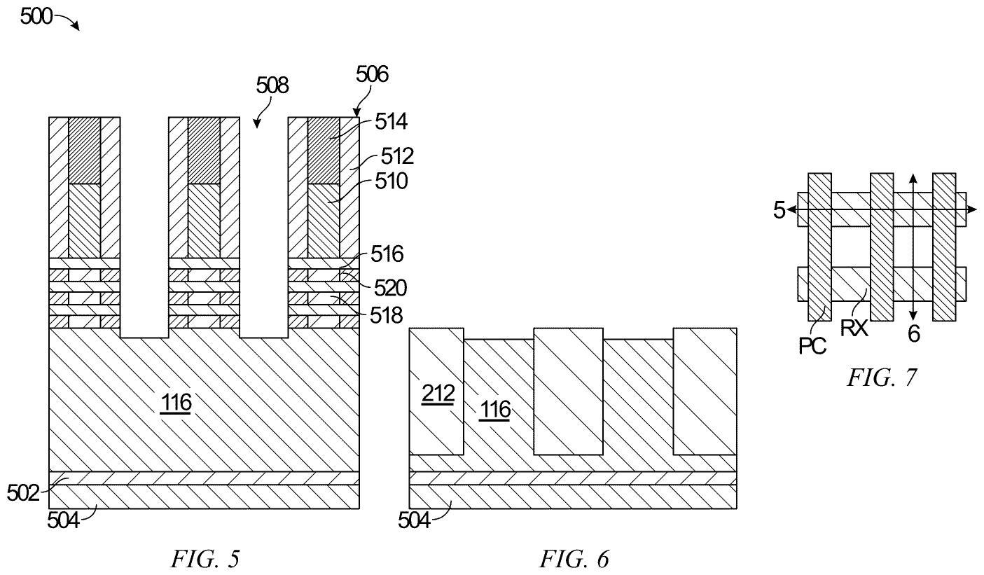

FIG. 4 depicts, in a flowchart 400, a method for making the CMOS apparatus that is shown in FIG. 1 through FIG. 3. FIG. 5 through FIG. 51 depict, in schematics, intermediate structures that are formed by steps of the method that is shown in FIG. 4. Various views of FIG. 5 through FIG. 51 are taken at view lines that are shown in certain other drawing figures; e.g., FIG. 5 and FIG. 6 are taken at view lines 5 and 6, respectively, in FIG. 7. Generally, for each intermediate structure such as structure 500, the first two figures (e.g., FIGS. 5 and 6) are sectional views taken along the corresponding numbered lines of the plan view (e.g., FIG. 7). In the plan views, PC denotes a “gate stack region” that is arranged from top to bottom of each plan view, whereas RX denotes active region which includes nanosheet channels and “source/drain regions” which are arranged from left to right of each plan view. In the plan views, CT shows the general disposition of the gate cut, while CA shows locations of frontside contacts. The ordinary skilled worker will appreciate that the gate stacks 120 align to the PC designation, whereas, e.g., the drain structure 104, and channels (Si sheets 516) align to the RX designation.

Referring to FIG. 4, and FIG. 5 through FIG. 7, at 402, a structure 500 is obtained that includes the substrate 116, an etch stop layer 502, an additional substrate 504, After nanosheet stack formation and patterning (including channel nanosheets 516 and sacrificial nanosheets 518), shallow trench isolation region 212 is formed to isolate different RX regions. After that, dummy gate 510 and gate hardmask 514 are deposited, followed by dummy gate patterning. Then, gate spacer 512 is formed, followed by nanosheet recess, sacrificial nanosheets indentation and inner spacer 520 formation. The ordinary skilled worker is familiar with methods for fabricating such structures.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures.

A number of different precursors may be used for the epitaxial deposition of the in situ doped semiconductor material. In some embodiments, the gas source for the deposition of an epitaxially formed in situ doped semiconductor material may include silicon (Si) deposited from silane, disilane, trisilane, tetrasilane, hexachlorodisilane, tetrachlorosilane, di chlorosilane, trichlorosilane, di silane and combinations thereof. In other examples, when the in situ doped semiconductor material includes germanium, a germanium gas source may be selected from the group consisting of germane, digermane, halogermane, dichlorogermane, trichlorogermane, tetrachlorogermane and combinations thereof. Examples of other epitaxial growth processes that can be employed in growing semiconductor layers described herein include rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE).

By “in-situ” it is meant that the dopant that dictates the conductivity type of doped layer is introduced during the process step, for example epitaxial deposition, that forms the doped layer. The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

As used herein, the term “conductivity type” denotes a dopant region being p-type or n-type. As further used herein, “p-type” refers to the addition of impurities to an intrinsic semiconductor that creates deficiencies of valence electrons. In a silicon-containing substrate, examples of p-type dopants, i.e., impurities include but are not limited to: boron, aluminum, gallium and indium. As used herein, “n-type” refers to the addition of impurities that contribute free electrons to an intrinsic semiconductor. Examples of n-type dopants, i.e., impurities in a silicon-containing substrate include but are not limited to antimony, arsenic and phosphorous.

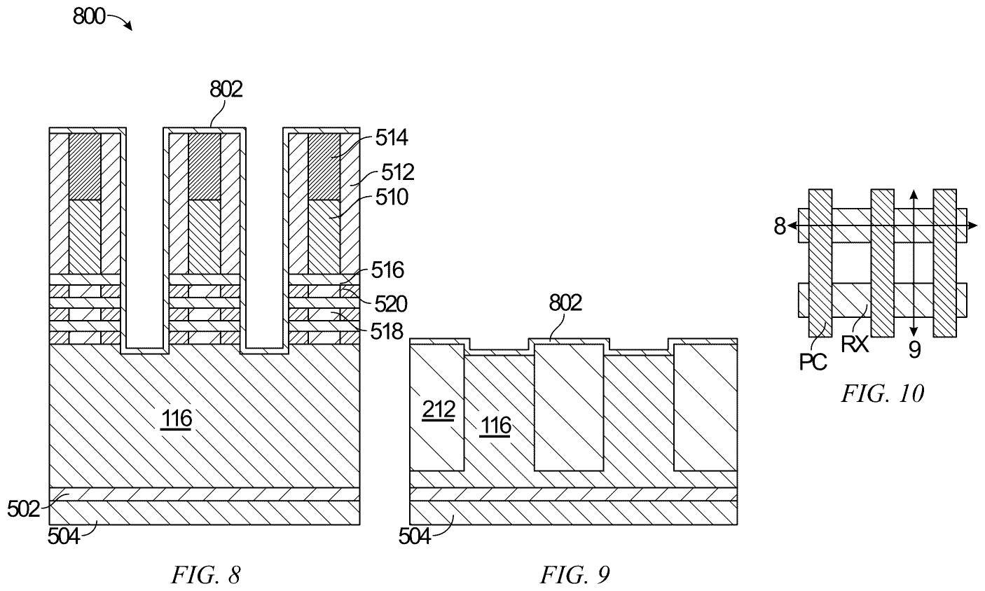

Referring to FIG. 4, and FIG. 8 through FIG. 10, at 404, form a structure 800 by depositing a protective liner 802 onto the structure 500. In one or more embodiments, the protective liner 802 can be composed of, e.g., silicon nitride, titanium nitride.

Referring to FIG. 4, and FIG. 11 through FIG. 13, at 406, form a structure 1100 by forming a masking layer 1102, such as, e.g., organic planarization layer (OPL) on the structure 800, then patterning the masking layer 1102 using conventional lithography and etch process, followed by opening the protective liner 802 and anisotropically etching the indentation 1104 into the substrate 116.

Those skilled in the art use numerous techniques to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

As an exemplary subtractive process, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

Referring to FIG. 4, and FIG. 14 through FIG. 16, at 408, form a structure 1400 that includes the sigma-profiled cavity 1402 by isotropically etching the substrate 116 from the indentation 1104, selective to the shallow trench isolation 212. An isotropic etch typically can be a wet etch process such as ammonia based chemistry or Tetramethylammonium hydroxide (TMAH), or a similar liquid solution, or can be a plasma dry etch process

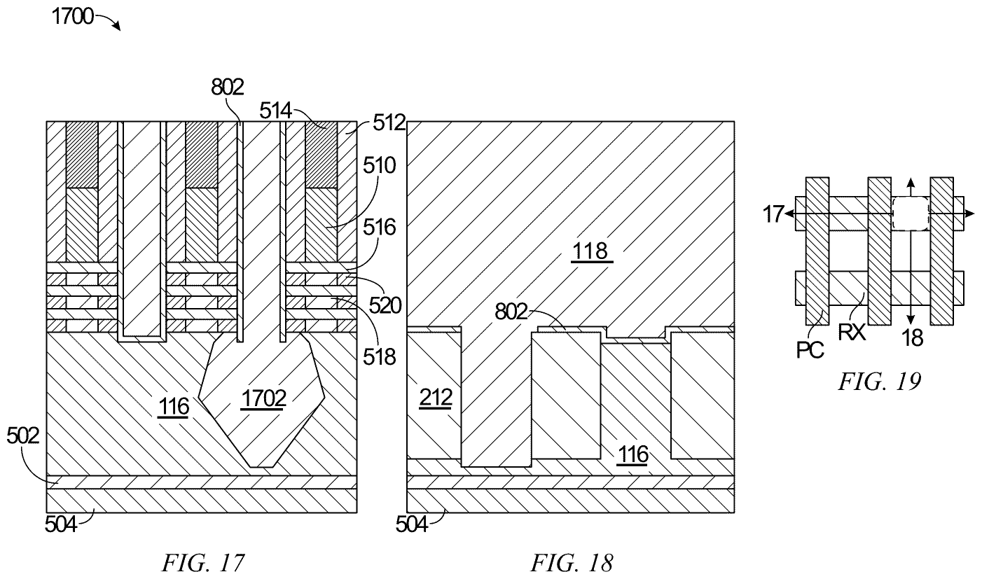

Referring to FIG. 4, and FIG. 17 through FIG. 19, at 410, fill the sigma-profiled cavity 1402 with a dielectric to form a sigma-profiled dielectric plug 1702 in a structure 1700. The ordinary skilled worker is familiar with methods (e.g., flowable oxide deposition) for adding material to a semiconductor structure. Element 118 is discussed immediately below.

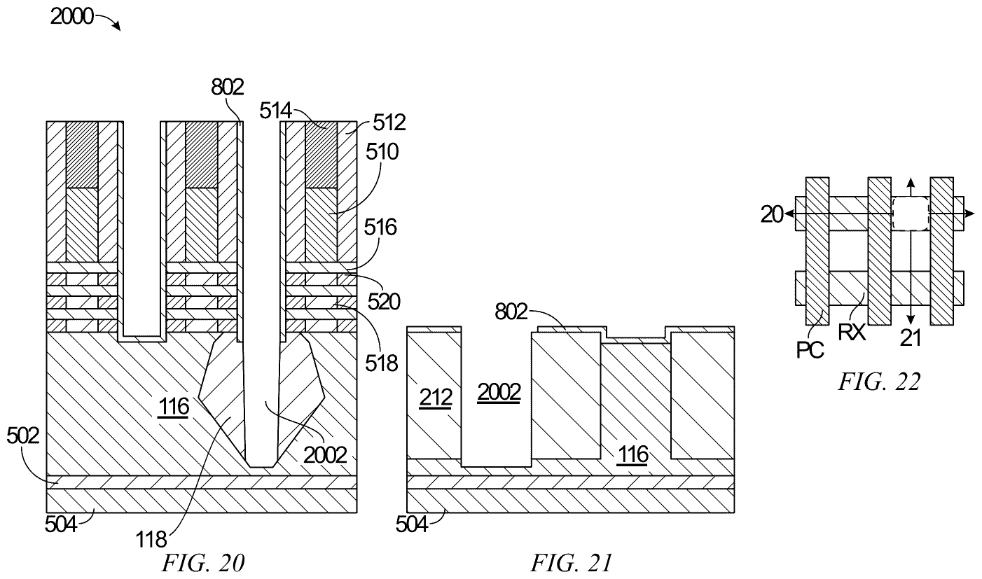

Referring to FIG. 4, and FIG. 20 through FIG. 22, at 412, etch the dielectric plug 1702 to form a trench 2002 in a structure 2000. The ordinary skilled worker is familiar with methods for removing material from a semiconductor structure. At this point, the dielectric plug 1702 becomes the dielectric structure 118 that is shown in, inter alia, FIG. 1 and FIG. 2.

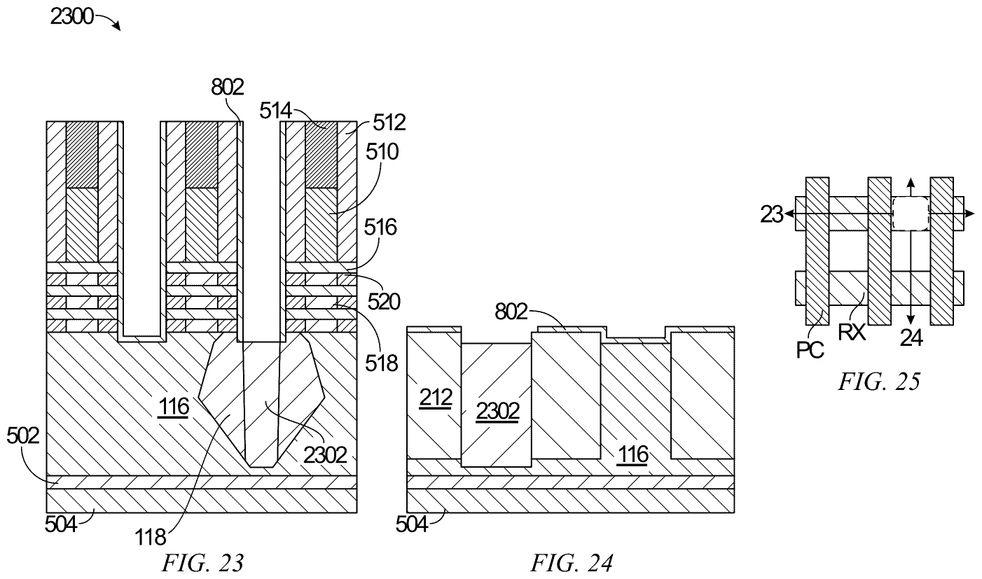

Referring to FIG. 4, and FIG. 23 through FIG. 25, at 416, fill the trench 2002 to form a structure 2300 by epitaxially growing, from the substrate 116, a plug 2302 of sacrificial material (i.e., a semiconductor material, like SiGe, or III-V material).

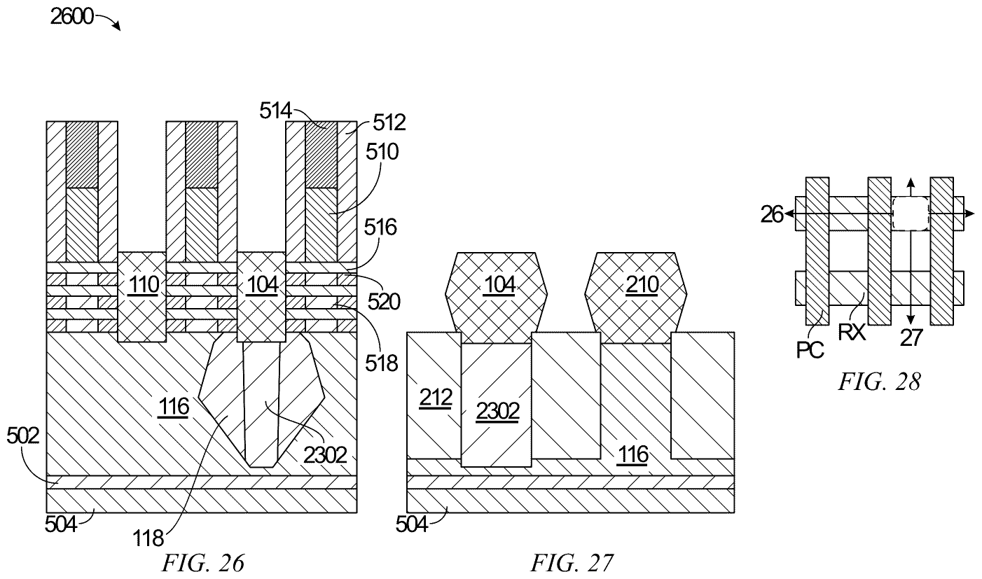

Referring to FIG. 4, and FIG. 26 through FIG. 28, at 418, form a structure 2600 by removing the protective liner 802 and epitaxially growing the first source/drain structure 104 from the sacrificial material plug 2302 while also epitaxially growing the second source/drain structure 110 and the third source/drain structure 210 from the substrate 116.

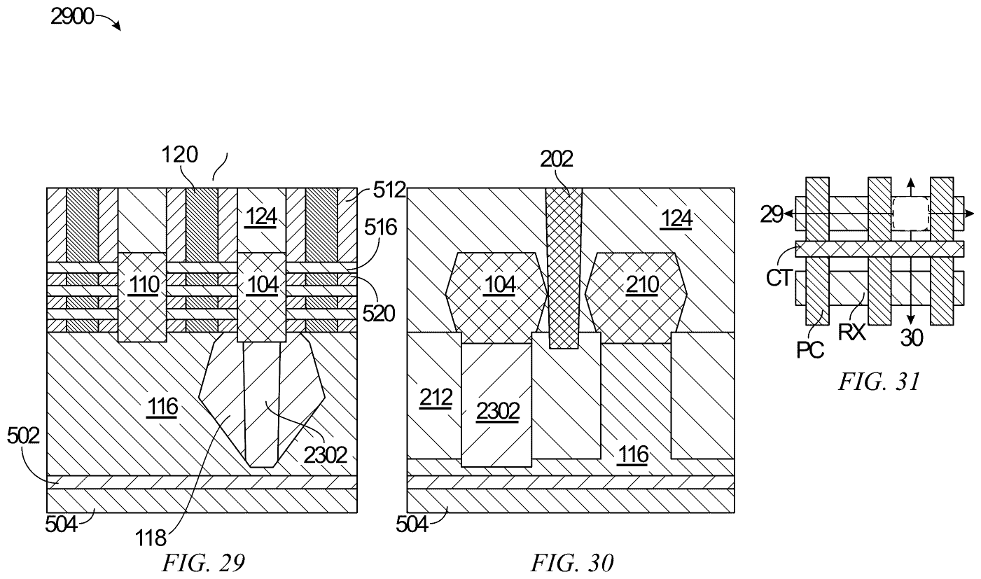

Referring to FIG. 4, and FIG. 29 through FIG. 31, at 420, deposit interlayer dielectric 124, replace the dummy gate stacks 510 with high-k/metal gate stacks 120, and planarize (e.g., by chemical-mechanical polishing) to form a structure 2900 that includes the gate stacks 120 and the gate cut (CT) 202, as shown in FIG. 1 and FIG. 2. The ordinary skilled worker is familiar with gate stacks. For example, gate stacks in both nFET and pFET structures (in embodiments having both types of regions) include a gate dielectric, such as HfO₂, ZrO₂, HfSiOₓ, HfLaOₓ, etc., and work function material (WFM) layers. Non-limiting examples of suitable work function (gate) metals include p-type work function materials and n-type work function materials. P-type work function materials include compositions such as ruthenium, palladium, platinum, cobalt, nickel, and conductive metal nitride like TiN, WN, or any combination thereof. N-type work function materials include compositions such as hafnium, zirconium, titanium, tantalum, aluminum, metal carbides (e.g., hafnium carbide, zirconium carbide, titanium carbide, and aluminum carbide), aluminides, or any combination thereof.

The work function material(s) may be deposited by a suitable deposition process, for example, ALD, CVD, PECVD, PVD, plating, and thermal or e-beam evaporation. Pinch-off of work function material between semiconductor fins is essentially avoided during deposition. The WFM layer is removed from one of the nFET and pFET regions in structures including both types of regions while the other region is protected. An SC1 etch, an SC2 etch or other suitable etch processes can be employed to remove the selected portion of the originally deposited WFM layer. A new WFM layer suitable for the region is then deposited. A device formed in the nFET region will accordingly include a WFM layer (gate electrode) having a first composition while a device in the pFET region will have a WFM layer having a second composition. For example, the WFM employed in an nFET region may be a Ti, Al, TiAl, TiAlC or TiAlC layer or a metal stack such as TiN/TiAl/TiN, TiN/TiAlC/TiN, TiN/TaAlC/TiN, or any combination of an aluminum alloy and TiN layers. The WFM layer employed in the pFET region may, for example, be a TiN, TiC, TaN or a tungsten (W) layer. The threshold voltage (Vt) of nFET devices is sensitive to the thickness of work function materials such as titanium nitride (TiN).

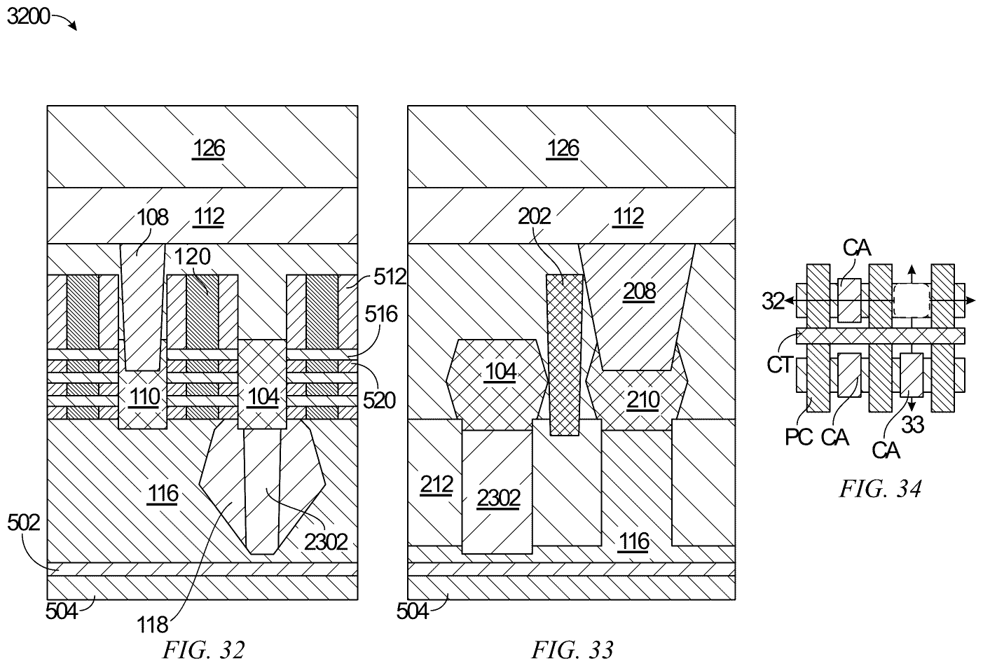

Referring to FIG. 4, and FIG. 32 through FIG. 34, at 422, form a structure 3200 that includes the frontside contacts 108 and 208, the frontside interconnect layer 112, and the carrier wafer 126. In one or more embodiments, contact material may, for example, include a silicide liner, such as Ti, Ni, NiPt, a metal adhesion layer, such as TiN, and conductive metal fills, such as W, Co, Ru, etc. The contact material may be deposited by, for example, CVD, PECVD, PVD, plating, thermal or e-beam evaporation, or sputtering. A planarization process such as ClVIP is performed to remove any electrically conductive material (overburden) from the top surface of the structure. The frontside interconnect layer 112 is usually referred to as a BEOL interconnect, which comprises multiple layers of metal interconnect wire and via layers. The carrier wafer 126 is formed over the frontside interconnect 112 by a wafer bonding process, which enables subsequent backside wafer processing.

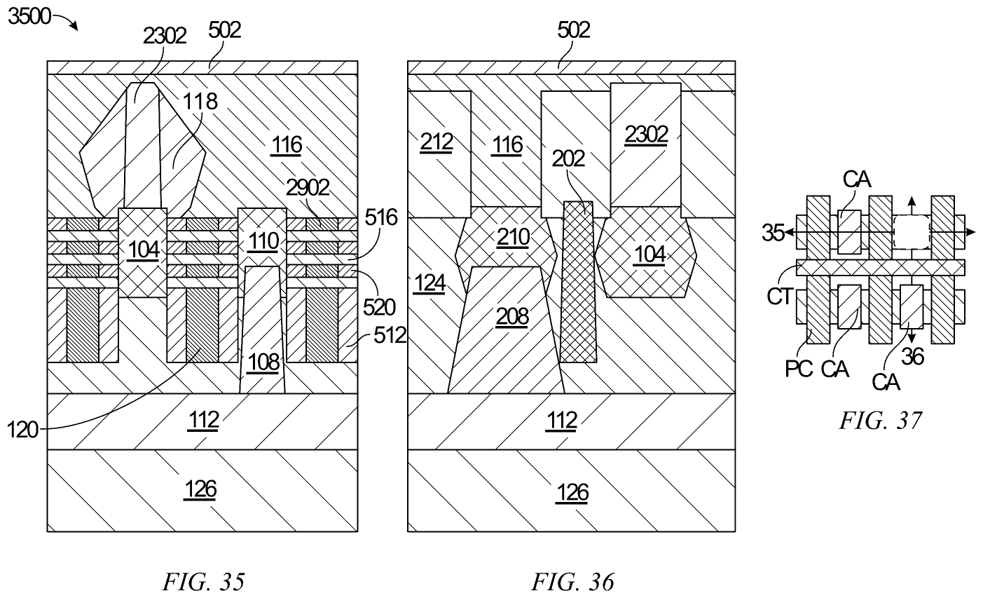

Referring to FIG. 4, and FIG. 35 through FIG. 37, at 424, form a structure 3500 by flipping the structure 3200 and etching away the additional substrate 504 down to the etch stop layer 502. In one or more embodiments, the etch stop layer is composed of a material that etches selective to the substrates 116, 504, e.g., if the substrates are silicon, the etch stop layer could be SiGe or SiGeC. The skilled artisan is familiar with techniques and fixtures for “flipping” wafers. Gate stack 120 is discussed above.

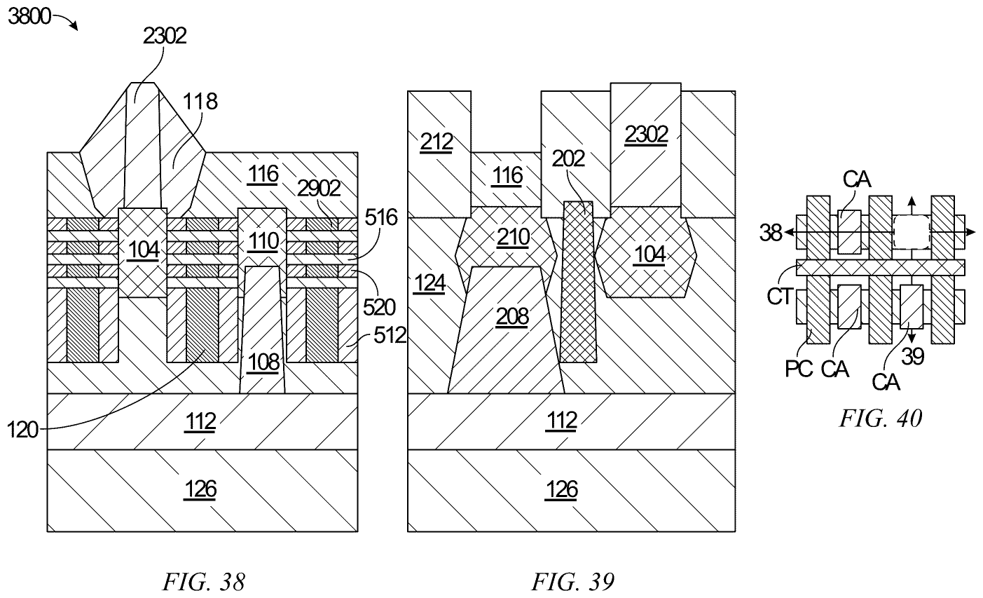

Referring to FIG. 4, and FIG. 38 through FIG. 40, at 426, form a structure 3800 by stripping the etch stop layer 502 and all but a remnant of the substrate 116, thereby revealing some of the dielectric structure 118 as well as a tip of the sacrificial material plug 2302. Typically, the stripping will be a two-step process, first to remove the etch stop layer and then to remove part of the substrate 116. In one or more embodiments, the process can be simplified by positioning the etch stop layer 502 “lower” in the flipped-over structure, so that simply etching to the etch stop layer and then stripping that layer alone will produce the desired structure.

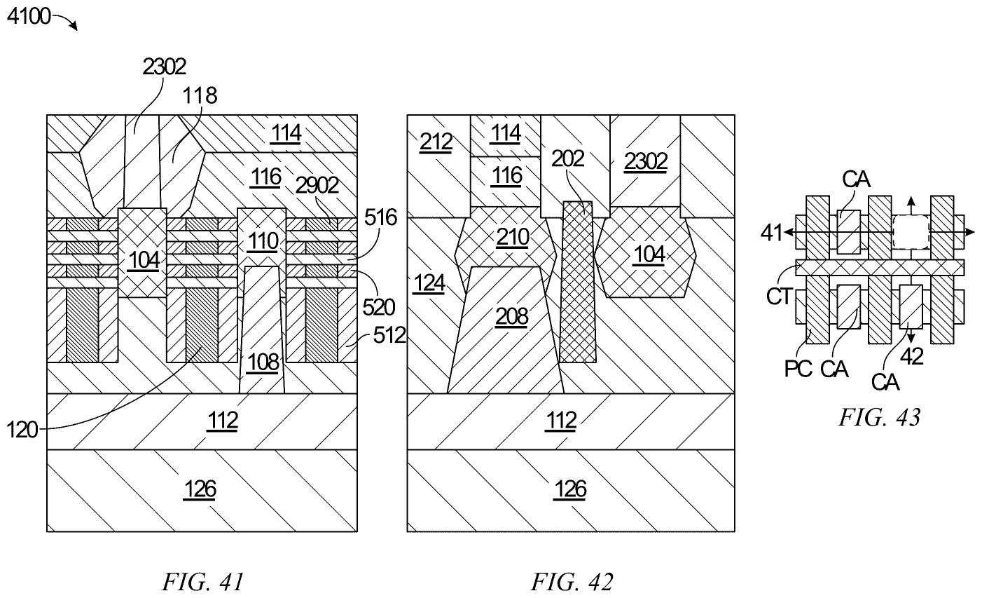

Referring to FIG. 4, and FIG. 41 through FIG. 43, at 428, form a structure 4100 by depositing the BILD 114, then planarizing to reveal more of the sacrificial material plug 2302. As previously mentioned, various processes can be used for planarization. The ordinary skilled worker is familiar with processes such as, e.g., CMP.

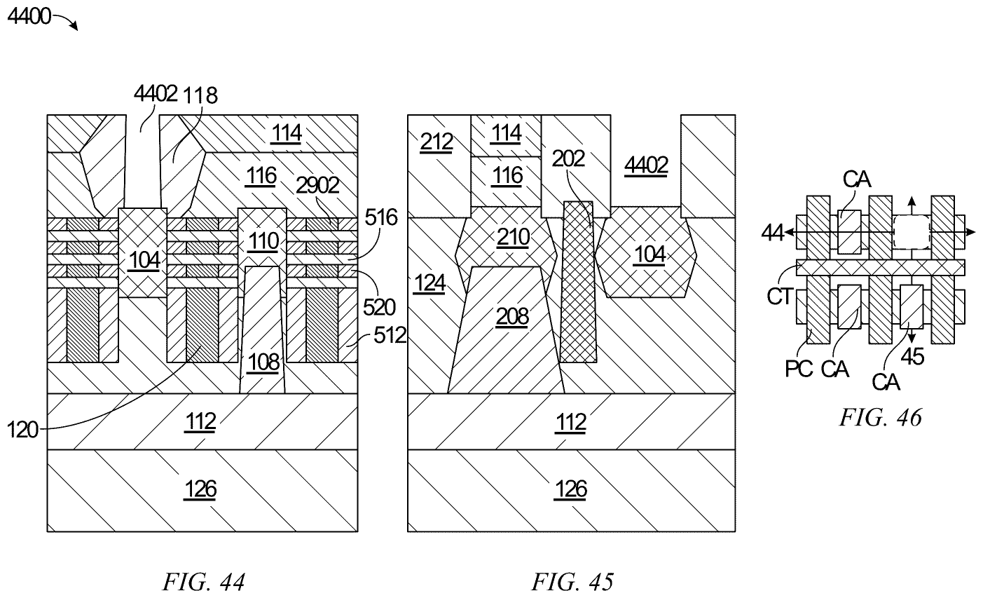

Referring to FIG. 4, and FIG. 44 through FIG. 46, at 430, remove the sacrificial material plug 2302 to form a backside contact trench 4402 in a structure 4400. A selective etch can be used. Preferably, if the substrate and the first source/drain structure are silicon, then the sacrificial material plug 2302 is silicon-germanium alloy or some other material that can be etched selective to silicon. Generally, the sacrificial material should etch selective to the substrate and to the first source/drain structure. In one or more embodiments, an isotropic etch can be used.

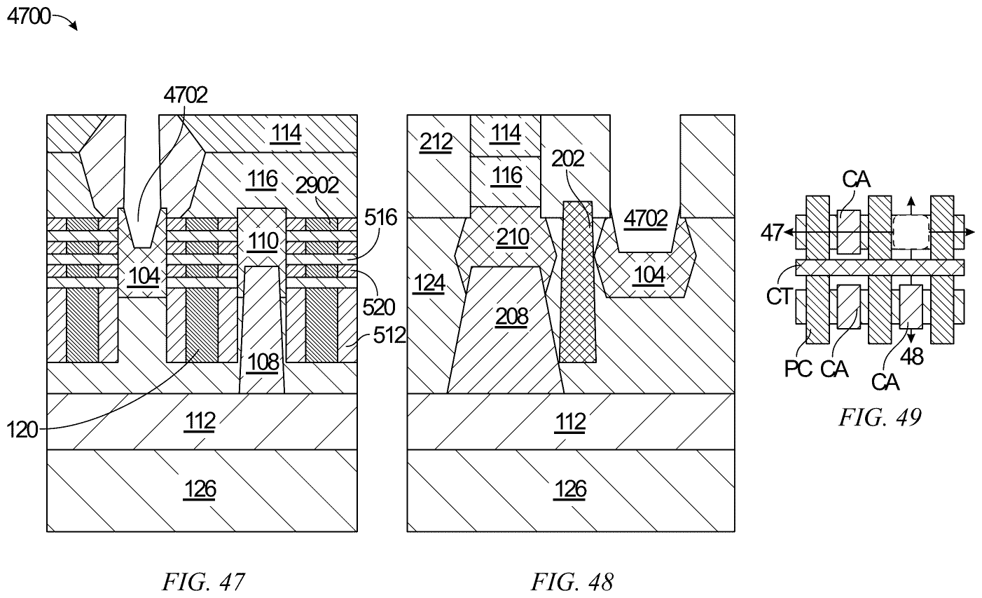

Referring to FIG. 4, and FIG. 47 through FIG. 49, at 432, form a structure 4700 by gouging (e.g., by reactive ion etching (RIE)) a gouge 4702 into the first source/drain structure 104 at the bottom of the cavity 4402. This can be formed by a conventional dry etch process.

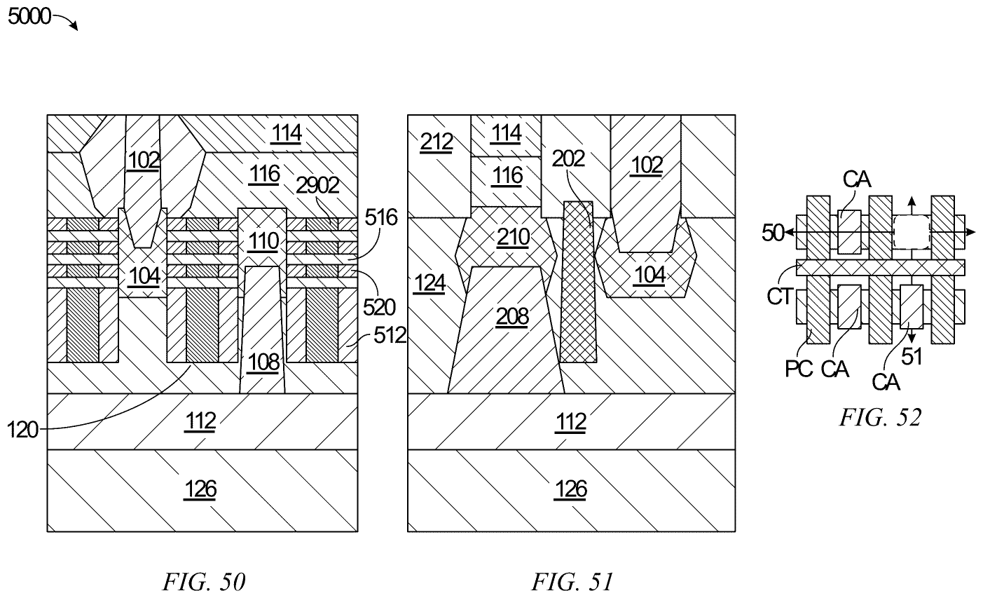

Referring to FIG. 4, and FIG. 50 through FIG. 52, at 434, fill the gouge 4702 and the backside contact trench 4402 with the SABC 102 to form structure 5000. As previously mentioned, the SABC 102 can comprise any one of, or an alloy of, several metals that are preferred for making contacts in semiconductor devices, which is similar to the contact metals in frontside contact 108/208.

Referring back to FIG. 1 through FIG. 3, at 436, complete the structure 100 by forming the backside interconnect layer 106 including the BSPR 107. The ordinary skilled worker is familiar with interconnect layers, which typically comprise multiple levels of metal and insulator to conduct electricity among selected semiconductor components.

Given the discussion thus far, it will be appreciated that, in general terms, an exemplary CMOS apparatus 100 includes a semiconductor substrate 116 that has a frontside 115 and a backside 113 opposite the frontside; and a first source/drain structure 110, which is disposed at the frontside of the substrate, and has a backside that contacts the frontside of the substrate and a frontside that is opposite the backside of the first source/drain structure. The CMOS apparatus 100 also includes a frontside interconnect layer 112, which is disposed at the frontside of the first source/drain structure; a frontside contact 108 that electrically connects the first source/drain structure to the frontside interconnect layer. The CMOS apparatus 100 also includes a second source/drain structure 104, which is disposed at the frontside of the substrate and has a backside that is adjacent to the substrate and a frontside that is opposite the backside of the second source/drain structure; a backside interconnect layer 106/107, which is disposed at the backside of the substrate; a backside contact 102, which penetrates the substrate and electrically connects the second source/drain structure to the backside interconnect layer; and a sigma-profiled dielectric structure 118 that insulates first and second sides of the backside contact from the substrate.

In one or more embodiments, the CMOS apparatus 100 also includes a backside interlayer dielectric 114, which is disposed between the substrate and the backside interconnect layer.

In one or more embodiments, the sigma-profiled dielectric structure and the backside contact penetrate both the substrate and the backside interlayer dielectric.

In one or more embodiments, the dielectric structure is widest at an interface between the backside interlayer dielectric and the substrate.

In one or more embodiments, the dielectric structure is narrowest at an interface between the backside interlayer dielectric and the backside interconnect layer.

In one or more embodiments, the dielectric structure has a first width C1 at an interface between the backside interlayer dielectric and the backside interconnect layer, a second width C2 at the backside of the second source/drain contact, and a third width C3 at an interface between the backside interlayer dielectric and the substrate, the first width is narrower than the second width and the second width is narrower than the third width.

In one or more embodiments, the CMOS apparatus 100 also includes shallow trench isolation 124 that insulates third and fourth sides of the backside contact from adjacent contacts.

According to another aspect, an exemplary CMOS apparatus includes a semiconductor substrate 116 that has a frontside 115 and a backside 113 opposite the frontside; a source/drain structure 104, which is disposed at the frontside of the substrate and has a backside that is adjacent to the substrate and a frontside that is opposite the backside of the source/drain structure; a backside interconnect layer 106/107, which is disposed at the backside of the substrate; a backside contact 102, which penetrates the substrate and electrically connects the source/drain structure to the backside interconnect layer; and a sigma-profiled dielectric structure 118 that insulates first and second sides of the backside contact from the substrate.

According to another aspect, an exemplary method 400 for making a CMOS apparatus 100 includes several steps. At 402-410, form a precursor structure 1700, which comprises a substrate 116 and a sigma-profiled dielectric plug 1702 embedded in the substrate. At 412, open a trench 2002 from a frontside of the substrate through the dielectric structure, thereby exposing the substrate at a backside end of the trench. At 414, epitaxially grow a sacrificial placeholder 2302 in the trench from the substrate through the dielectric structure. At 418, epitaxially grow a first source/drain structure 104 from the sacrificial placeholder at the frontside of the substrate.

In one or more embodiments, the method 400 also includes, at 424, flipping the precursor structure; and, at 430, forming a backside contact trench 4402 in the dielectric structure by removing the sacrificial placeholder down to a backside of the first source/drain structure.

In one or more embodiments, the method 400 also includes, at 432, gouging a gouge 4702 into the backside of the first source/drain structure from the backside contact trench.

In one or more embodiments, the method 400 also includes, before flipping the precursor: at 418, epitaxially growing a second source/drain structure 110 at the frontside of the substrate along with the first source/drain structure; and, at 422, forming a frontside interconnect layer 112, at the frontside of the first and second source/drain structures, which is electrically connected to the frontside of the second source/drain structure.

In one or more embodiments, the method 400 also includes, as part of obtaining the precursor structure: at 406, anisotropically etching an indentation 1104 into the substrate between two dummy gates that protrude from the frontside of the substrate; and, at 408, isotropically etching a sigma-profiled cavity 1402 from the indentation.

In one or more embodiments, the method 400 also includes forming the sigma-profiled dielectric plug by, at 410, filling the sigma-profiled cavity with a dielectric.

In one or more embodiments, the method 400 also includes, before etching the indentation into the substrate, at 404, forming a protective liner 802 on mutually facing sides of the two dummy gates.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A CMOS apparatus that comprises:
a semiconductor substrate that has a frontside and a backside opposite the frontside;
a first source/drain structure, which is disposed at the frontside of the substrate, wherein the first source/drain structure has a backside that contacts the frontside of the substrate and the first source/drain structure has a frontside that is opposite the backside of the first source/drain structure;
a frontside interconnect layer, which is disposed at the frontside of the first source/drain structure;
a frontside contact that electrically connects the first source/drain structure to the frontside interconnect layer;
a second source/drain structure, which is disposed at the frontside of the substrate, wherein the second source/drain structure has a backside that is adjacent to the substrate and the second source/drain structure has a frontside that is opposite the backside of the second source/drain structure;
a backside interconnect layer, which is disposed at the backside of the substrate;
a backside contact, which penetrates the substrate and electrically connects the second source/drain structure to the backside interconnect layer; and
a sigma-profiled dielectric structure that insulates first and second sides of the backside contact from the substrate.

2. The CMOS apparatus of claim 1, further comprising:
a backside interlayer dielectric, which is disposed between the substrate and the backside interconnect layer.

3. The CMOS apparatus of claim 2, wherein the sigma-profiled dielectric structure and the backside contact penetrate both the substrate and the backside interlayer dielectric.

4. The CMOS apparatus of claim 3, wherein the sigma-profiled dielectric structure is widest at an interface between the backside interlayer dielectric and the substrate.

5. The CMOS apparatus of claim 3, wherein the sigma-profiled dielectric structure is narrowest at an interface between the backside interlayer dielectric and the backside interconnect layer.

6. The CMOS apparatus of claim 3, wherein the sigma-profiled dielectric structure has a first width at an interface between the backside interlayer dielectric and the backside interconnect layer, a second width at the backside of the second source/drain contact, and a third width at an interface between the backside interlayer dielectric and the substrate, the first width is narrower than the second width and the second width is narrower than the third width.

7. The CMOS apparatus of claim 1, further comprising:
shallow trench isolation that insulates third and fourth sides of the backside contact from adjacent contacts.

8. A CMOS apparatus that comprises:
a semiconductor substrate that has a frontside and a backside opposite the frontside;
a source/drain structure, which is disposed at the frontside of the substrate, wherein the source/drain structure has a backside that is adjacent to the substrate and the source/drain structure has a frontside that is opposite the backside of the source/drain structure;
a backside interconnect layer, which is disposed at the backside of the substrate;
a backside contact, which penetrates the substrate and electrically connects the source/drain structure to the backside interconnect layer; and
a sigma-profiled dielectric structure that insulates first and second sides of the backside contact from the substrate.

9. The CMOS apparatus of claim 8, further comprising:
a backside interlayer dielectric, which is disposed between the substrate and the backside interconnect layer.

10. The CMOS apparatus of claim 9, wherein the sigma-profiled dielectric structure and the backside contact penetrate both the substrate and the backside interlayer dielectric.

11. The CMOS apparatus of claim 10, wherein the sigma-profiled dielectric structure is widest at an interface between the backside interlayer dielectric and the substrate.

12. The CMOS apparatus of claim 10, wherein the sigma-profiled dielectric structure is narrowest at an interface between the backside interlayer dielectric and the backside interconnect layer.

13. The CMOS apparatus of claim 10, wherein the sigma-profiled dielectric structure has a first width at an interface between the backside interlayer dielectric and the backside interconnect layer, a second width at the backside of the second source/drain contact, and a third width at an interface between the backside interlayer dielectric and the substrate, the first width is narrower than the second width and the second width is narrower than the third width.

14. A method for making a CMOS apparatus, the method comprising:
forming a precursor structure, which comprises a substrate and a sigma-profiled dielectric plug embedded in the substrate;
opening a trench from a frontside of the substrate through the dielectric structure, wherein the trench exposes the substrate at a backside end of the trench;
epitaxially growing a sacrificial placeholder in the trench from the substrate through the dielectric structure; and
epitaxially growing a first source/drain structure from the sacrificial placeholder at the frontside of the substrate.

15. The method of claim 14, further comprising:
flipping the precursor structure; and
forming a backside contact trench in the dielectric structure by removing the sacrificial placeholder down to a backside of the first source/drain structure.

16. The method of claim 15, further comprising:
gouging a gouge into the backside of the first source/drain structure from the backside contact trench.

17. The method of claim 15, further comprising, before flipping the precursor:
epitaxially growing a second source/drain structure at the frontside of the substrate along with the first source/drain structure; and
forming a frontside interconnect layer, at the frontside of the first and second source/drain structures, which is electrically connected to the frontside of the second source/drain structure.

18. The method of claim 14, further comprising, as part of obtaining the precursor structure:
anisotropically etching an indentation into the substrate between two dummy gates that protrude from the frontside of the substrate; and
isotropically etching a sigma-profiled cavity from the indentation.

19. The method of claim 18, further comprising:
forming the sigma-profiled dielectric plug by filling the sigma-profiled cavity with a dielectric.

20. The method of claim 19, further comprising, before etching the indentation into the substrate:
forming a protective liner on mutually facing sides of the two dummy gates.
